(19) United States
(12) Patent Application Publication
(10) Pub. No.: US 2008/0308902 A1
(43) Pub. Date: Dec. 18, 2008

(54) SEMICONDUCTOR DEVICE

(75) Inventors: Yoshinori KUMURA, Yokohama-Shi (JP); Tohru Ozaki, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/125,557

(22) Filed: May 22, 2008

(30) Foreign Application Priority Data
Jun. 12, 2007 (JP) 2007-154949

(51) Int. Cl. H01L 29/00; H01L 21/00

(52) U.S. Cl. 257/532; 438/3; 257/E29.001; 257/E21.001

(57) ABSTRACT

This disclosure concerns a semiconductor device comprising a switching transistor provided on a semiconductor substrate; an interlayer dielectric film formed on the switching transistor; a ferroelectric capacitor including an upper electrode, a ferroelectric film, and a lower electrode formed on the interlayer dielectric film; a contact plug provided in the interlayer dielectric film and electrically connected to the lower electrode; a diffusion layer connecting between the contact plug and the switching transistor; a trench formed around the ferroelectric capacitor; and a barrier film filling in the trench and provided on a side surface of the ferroelectric capacitor and on an upper surface of the interlayer dielectric film, the barrier film suppressing percolation of hydrogen, wherein a thickness of the barrier film on the side surface of the ferroelectric capacitor is larger than a thickness of the barrier film on the upper surface of the interlayer dielectric film.

### CROSS-REFERENCE TO RELATED APPLICATION

This application is based upon and claims the benefit of priority from the prior Japanese Patent Application No. 2007-154949, filed on Jun. 12, 2007, the entire contents of which are incorporated herein by reference.

### BACKGROUND OF THE INVENTION

1. Field of the Invention

The present invention relates to a semiconductor device, and relates to a ferroelectric memory having a ferroelectric capacitor, for example.

2. Related Art

Along with the miniaturization of a ferroelectric memory device, damage to a ferroelectric capacitor becomes remarkable. As one of causes for this, there is an influence of hydrogen entering from a contact portion of an upper electrode. For example, there is a process of embedding tungsten into a contact hole formed on the upper electrode. The tungsten deposition process is performed in the atmosphere containing a large amount of hydrogen. Therefore, hydrogen enters from a side surface of a ferroelectric film, and degrades a ferroelectric material.

To solve this problem, a barrier film blocking hydrogen is provided to cover the ferroelectric capacitor. However, along the progress of high integration, a taper angle of the side surface of the ferroelectric capacitor and an aspect ratio between the ferroelectric capacities becomes high. Therefore, it becomes difficult to deposit a barrier film having a sufficient film thickness on the side surface of the ferroelectric capacitor, and degrades the ferroelectric material by hydrogen.

### SUMMARY OF THE INVENTION

A semiconductor device according to an embodiment of the present invention comprises a switching transistor provided on a semiconductor substrate; an interlayer dielectric film formed on the switching transistor; a ferroelectric capacitor including an upper electrode, a ferroelectric film, and a lower electrode formed on the interlayer dielectric film; a contact plug provided in the interlayer dielectric film and electrically connected to the lower electrode; a diffusion layer connecting between the contact plug and the switching transistor; a trench formed around the ferroelectric capacitor; and a barrier film filling in the trench and provided on a side surface of the ferroelectric capacitor and on an upper surface of the interlayer dielectric film, the barrier film suppressing percolation of hydrogen, wherein a thickness of the barrier film on the side surface of the ferroelectric capacitor is larger than a thickness of the barrier film on the upper surface of the interlayer dielectric film.

A method of manufacturing a semiconductor device according to an embodiment of the present invention, the semiconductor device including a ferroelectric capacitor including an upper electrode, a ferroelectric film, and a lower electrode, the manufacturing method comprises forming a switching transistor on a semiconductor substrate and forming a diffusion layer connected to the switching transistor; forming a first interlayer dielectric film on the switching transistor; forming a contact plug connected to the diffusion layer in the first interlayer dielectric film; forming the ferroelectric capacitor on the contact plug; depositing a first barrier film suppressing percolation of hydrogen on the ferroelectric capacitor and on the first interlayer dielectric film; depositing a second interlayer dielectric film on the first barrier film; forming a trench between the side surface of the ferroelectric capacitor and the second interlayer dielectric film by etching the second interlayer dielectric film around the ferroelectric capacitor; and filling a second barrier film into the trench.

### BRIEF DESCRIPTION OF THE DRAWINGS

FIG. 1 is a cross-sectional view showing a configuration of a ferroelectric memory according to a first embodiment of the present invention;

FIG. 2 is a cross-sectional view showing one example of the ferroelectric memory according to the first embodiment;

FIGS. 3 to 9 are cross-sectional views showing a method of manufacturing the ferroelectric memory according to the first embodiment;

FIG. 10 is a cross-sectional view of a ferroelectric memory according to a second embodiment of the present invention;

FIGS. 11 to 15 are cross-sectional views showing a method of manufacturing the ferroelectric memory according to the second embodiment;

FIG. 16 is a cross-sectional view of a ferroelectric memory according to a third embodiment of the present invention;

FIG. 17 is a top plan view of a layer along a line 17-17 in FIG. 16;

FIG. 18 is a cross-sectional view of a ferroelectric memory according to a fourth embodiment of the present invention;

FIG. 19 is a cross-sectional view of a ferroelectric memory according to a fifth embodiment of the present invention;

FIG. 20 is a cross-sectional view of a ferroelectric memory according to a sixth embodiment of the present invention;

FIGS. 21A and 21B are top plan views showing a relationship between a barrier film BM4 and the contact plug CP3;

FIG. 22 is a cross-sectional view of a ferroelectric memory according to a seventh embodiment of the present invention;

FIG. 23 is a cross-sectional view showing a contact portion of the peripheral circuit region of the ferroelectric memory according to the seventh embodiment; and

FIGS. 24 and 25 are cross-sectional views showing a method of manufacturing the ferroelectric memory according to the seventh embodiment.

### DETAILED DESCRIPTION OF THE INVENTION

Embodiments of the present invention will be explained below in detail with reference to the accompanying drawings. Note that the invention is not limited thereto.

### First Embodiment

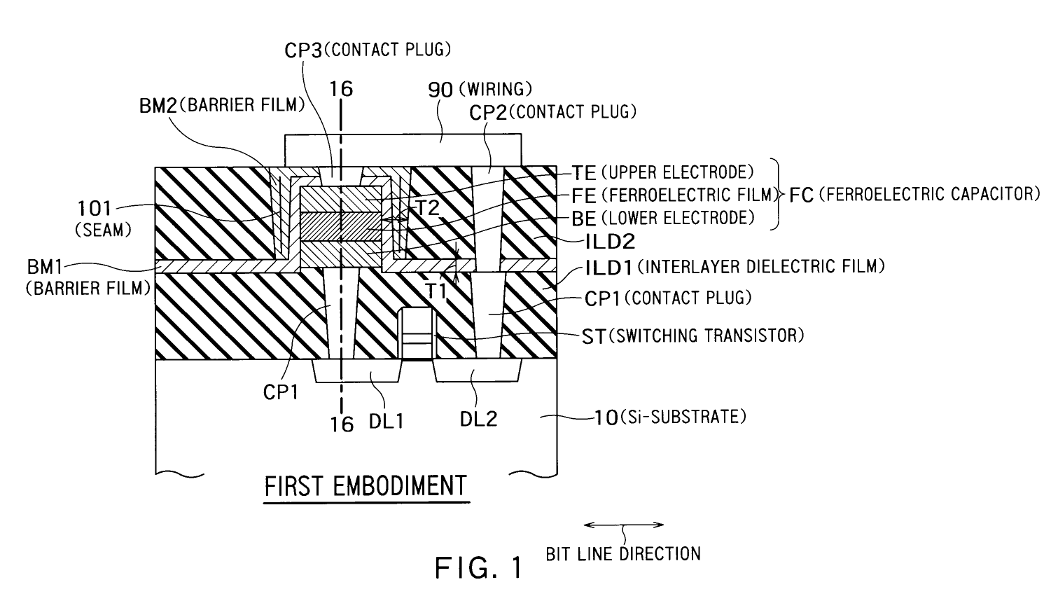

FIG. 1 is a cross-sectional view showing a configuration of a ferroelectric memory according to a first embodiment of the present invention. The ferroelectric memory according to the present embodiment includes a silicon substrate 10, a switching transistor ST provided on the silicon substrate 10, an interlayer dielectric film ILD1 formed on the switching transistor ST, and a ferroelectric capacitor FC provided on the interlayer dielectric film ILD1. The ferroelectric capacitor FC is two-dimensionally laid out in a matrix above the silicon oxide film substrate 10.

The ferroelectric capacitor FC includes a lower electrode BE provided on the interlayer dielectric film ILD1, a ferroelectric film FE provided on the lower electrode BE, and an upper electrode TE provided on the ferroelectric film FE. The switching transistor ST includes source and drain diffusion layers DL1 and DL2. A contact plug CP1 is embedded into the interlayer dielectric film ILD1 beneath the lower electrode BE. The contact plug CP1 connects between the lower electrode BE and the diffusion layer DL1. Accordingly, the switching transistor ST is electrically connected to the lower electrode BE via the contact plug CP1. The lower electrode material includes a single-layer film such as Ti, TiN, TiAlN, Pt, Ir, IrO₂, SrRuO₃ (hereinafter, also called SRO), Ru, and RuO₂, or includes a lamination film including at least two of them. A ferroelectric material FE includes PZT (Pb(ZrₓTi₍₁₋ₓ₎O₃), SBT (SrₓBi_{y}Ta_{z}Oₐ), and BLT (BiₓLa_{y}O_{z}). In the above, x, y, z, a are positive numerals. In the present embodiment, the ferroelectric material FE includes PZT. An upper electrode material TE includes a single-layer film such as Pt, Ir, IrO₂, SRO, Ru, and RuO₂, or a lamination film including at least two of them.

A barrier film BM1 is provided on the side surface and the upper surface of the ferroelectric capacitor FC, and on the interlayer dielectric film ILD1. The barrier film BM1 includes a single-layer film of Al₂O₃, SiN, and TiO₂, or a lamination film of two or more of these films. The barrier film BM1 including these materials has a characteristic of suppressing percolation of hydrogen, and interrupting hydrogen.

Further, a barrier film BM2 is provided on the side surface of the ferroelectric capacitor FC via the barrier film BM1. The barrier film BM2 includes Al₂O₃, SiN, or TiO₂. The barrier film BM2 can be made of the same material as that of the barrier film BM1, or a different material. The barrier film BM2 is a single continuous layer folded down into a trench 50 between a side surface of the barrier film BM1 and a side surface of the interlayer dielectric film ILD2. Therefore, the barrier film BM2 includes a seam 101 extending along with the side surface of the barrier film BM1 and with the side surface of the interlayer dielectric film ILD2. The seam 101 is provided at an intermediate portion between the side surface of the barrier film BM1 and the side surface of the interlayer dielectric film ILD2.

An interlayer dielectric film ILD2 is provided on the barrier films BM1 and BM2. The interlayer dielectric film ILD2 includes P-TEOS, O₃-TEOS, SOG (Spin On Glass), and Low-k films (SiOF, SiOC). The interlayer dielectric film ILD1 includes BPSG (Boron Phosphorous Silicate Glass), and P-TEOS (Plasma-Tetra Ethoxy Silane). Contact plugs CP2 and CP3 are embedded into the interlayer dielectric film ILD2. The contact plug CP2 is electrically connected to a diffusion layer DL2. The contact plug CP3 is connected to the upper electrode TE. The contact plugs CP2 and CP3 are connected to each other by a wiring 90 provided on the interlayer dielectric film ILD2. The contact plug CP1 includes tungsten or doped polysilicon. The contact plugs CP2 and CP3 include materials of W, Al, TiN, Cu, Ti, Ta, and TaN.

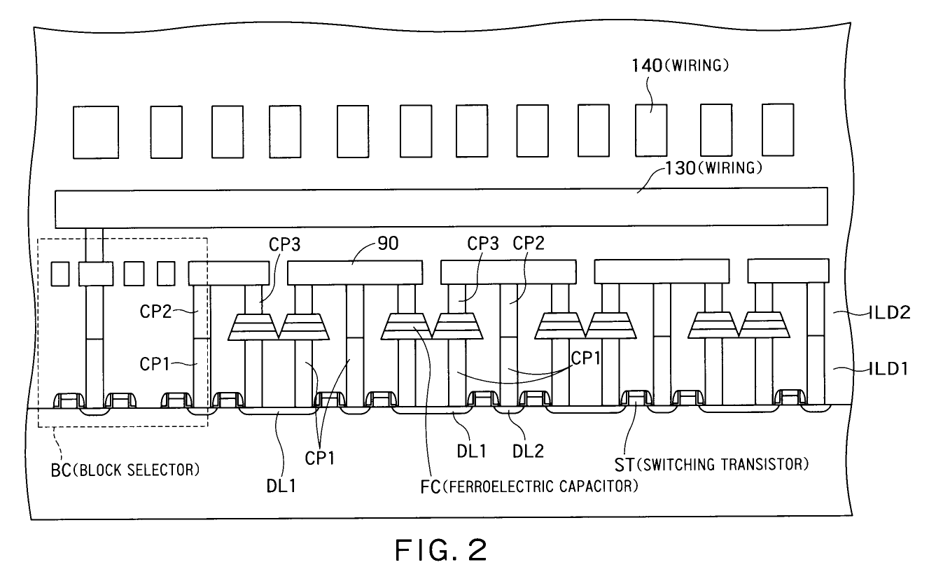

FIG. 2 is a cross-sectional view showing one example of the ferroelectric memory according to the first embodiment. FIG. 2 shows a memory which consists of series connected memory cells each having a transistor having a source terminal and a drain terminal and a ferroelectric capacitor inbetween said two terminals, hereafter named “Series connected TC unit type ferroelectric RAM” The present embodiment can be also applied to an optional memory having a ferroelectric capacitor, not only to the TC parallel unit series-connection-type ferroelectric memory.

While the side surface of the ferroelectric capacitor FC is etched substantially perpendicularly in FIG. 1, the side surface is actually formed in a sequentially tapered shape as shown in FIG. 2. In FIG. 2, the barrier films BM1 and BM2 are omitted. FIG. 1 is a cross-sectional view along a first direction (a bit line direction) having plural unit cells connected in series.

Referring back to FIG. 1 again, in the present embodiment, a thickness T2 of the barrier films BM1 and BM2 on the side surface of the ferroelectric capacitor FC is larger than a thickness T1 of the barrier film BM1 on the upper surface of the interlayer dielectric film ILD1. The thickness T2 is a thickness in a direction perpendicular to the side surface of the ferroelectric capacitor FC. The thickness T1 is a thickness in a direction perpendicular to the upper surface of the interlayer dielectric film ILD1. Accordingly, in the process of forming the contact plugs CP2 and CP3, hydrogen can be prevented from entering the side surface of the ferroelectric film FE.

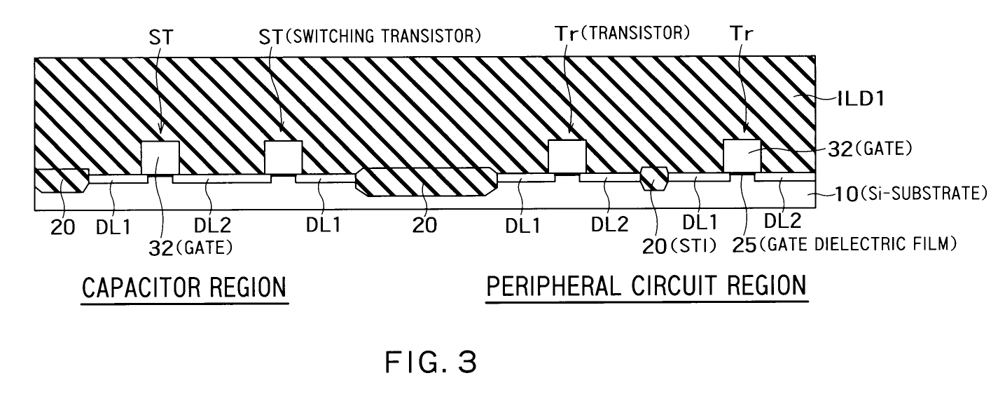

A method of manufacturing the ferroelectric memory according to the first embodiment is explained with reference to FIG. 3 to FIG. 9. In the drawings, a capacitor region and a peripheral circuit region are displayed together. First, as shown in FIG. 3, ST1 (Shallow Trench Isolation) is formed on a silicon substrate 10 as an element isolation part 20. A gate dielectric film 25 is formed on a surface of the silicon substrate 10, and a gate electrode 32 is formed on the gate dielectric film 25. Source and drain layers DL1 and DL2 are formed at both sides of the channel region by introducing an impurity, using the gate electrode 32 as a mask. As a result, the switching transistor ST is formed in the capacitor region, and a transistor Tr as an element configuring a circuit is formed in the peripheral circuit region. Next, the interlayer dielectric film ILD1 is deposited on the silicon substrate 10, the switching transistor ST, and the transistor Tr. The surface of the interlayer dielectric film ILD1 is ground flat by using CMP (Chemical Mechanical Polishing). As a result, a structure shown in FIG. 3 is obtained. The gate dielectric film, and both or either one of the gate electrode and the source and drain layers can be simultaneously formed in the capacitor region and the peripheral circuit region, or can be formed in individual processes.

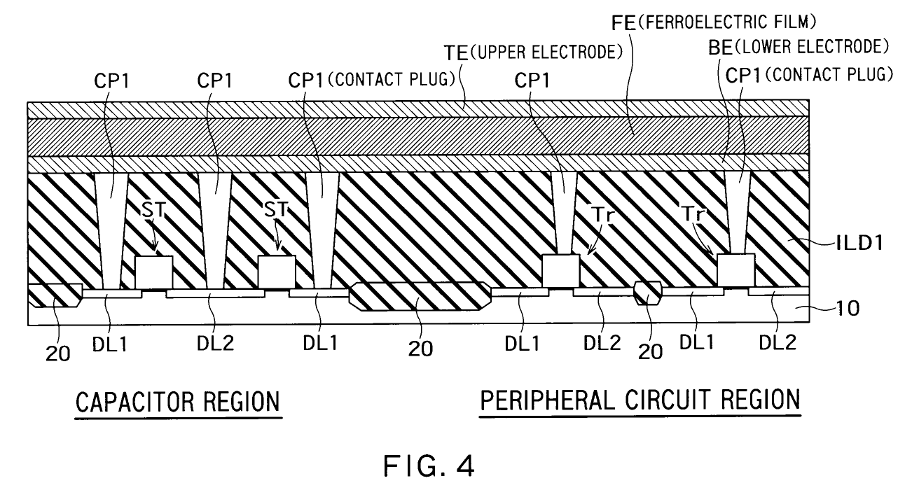

A contact hole communicating to the diffusion layers DL1 and DL2 is formed within the interlayer dielectric film ILD1 by using lithography and RIE (Reactive Ion Etching). Further, metal or doped polysilicon is embedded into the contact hole, and the metal or the doped polysilicon is flattened using CMP. As a result, a contact plug CP1 is formed, as shown in FIG. 4. The contact plug CP1 in the capacitor region and the contact plug CP1 in the peripheral circuit region can be formed simultaneously, or can be formed in individual processes.

Next, as shown in FIG. 4, the lower electrode material BE, the ferroelectric material FE, and the upper electrode material TE are deposited on the interlayer dielectric film ILD1 and the contact plug CP1. As described above, the lower electrode material BE includes a single-layer film such as Ti, TiN, TiAlN, Pt, Ir, IrO₂, SRO, Ru, and RuO₂, or includes a lamination film including at least two of them. The ferroelectric material FE includes PZT, SBT, or BLT, for example. The upper electrode material TE includes a single-layer film such as Pt, Ir, IrO₂, SRO, Ru, and RuO₂, or a lamination film of these.

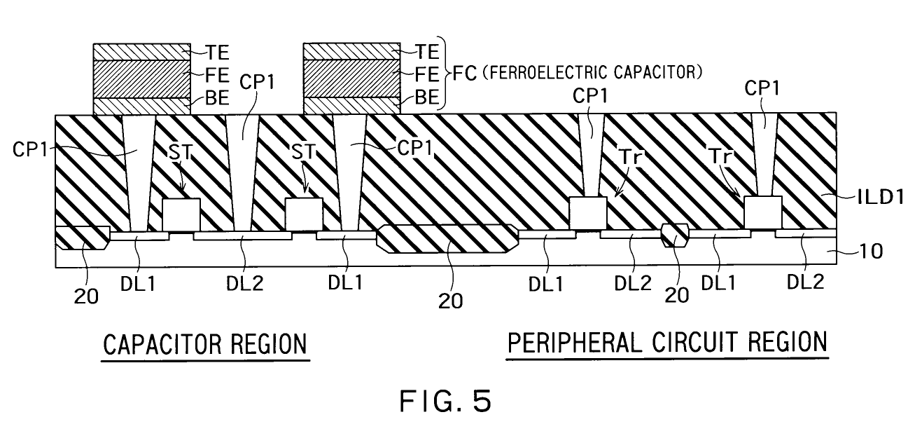

Next, a mask material (not shown) is deposited on the upper electrode material TE. The mask material includes a P-TEOS film, an O₃-TEOS film, or an Al₂O₃. The mask material is processed into a pattern of a ferroelectric capacitor by using lithography or RIE. The upper electrode material TE, the ferroelectric material FE, and the bottom electrode material BE are etched by RIE, using the processed mask material as a mask. As a result, as shown in FIG. 5, the ferroelectric capacitor FC is formed on the contact plug CP1. The upper electrode material TE, the ferroelectric material FE, and the bottom electrode material BE after the processing are called an upper electrode TE, a ferroelectric FE, and a bottom electrode BE.

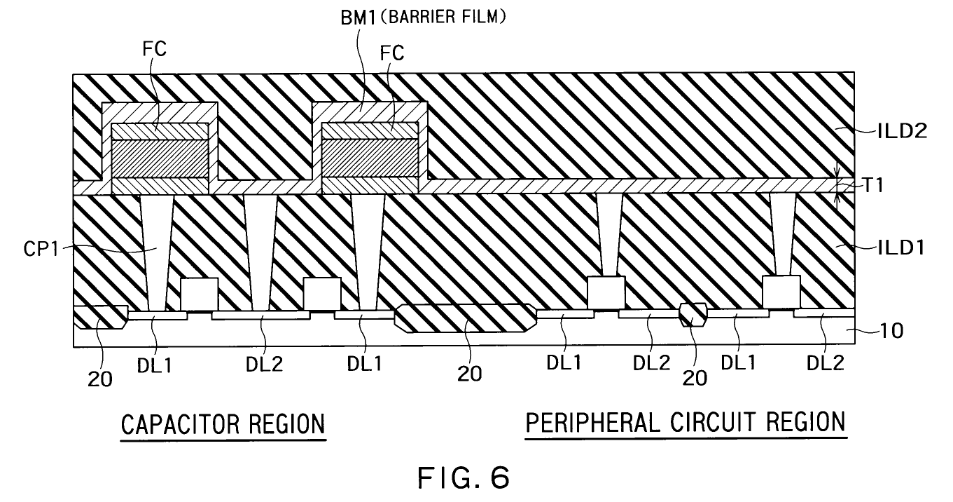

Next, as shown in FIG. 6, a barrier film BM1 is deposited on the side surface and the upper surface of the ferroelectric capacitor FC, and on the interlayer dielectric film ILD1. The barrier film BM1 includes a single-layer film such as Al₂O₃, SiN, and TiO₂, or a lamination film of two or more of these films. A film thickness of the barrier film BM1 is T1. The interlayer dielectric film ILD2 is deposited on a barrier film BM1, and the interlayer dielectric film ILD2 is flattened using CMP.

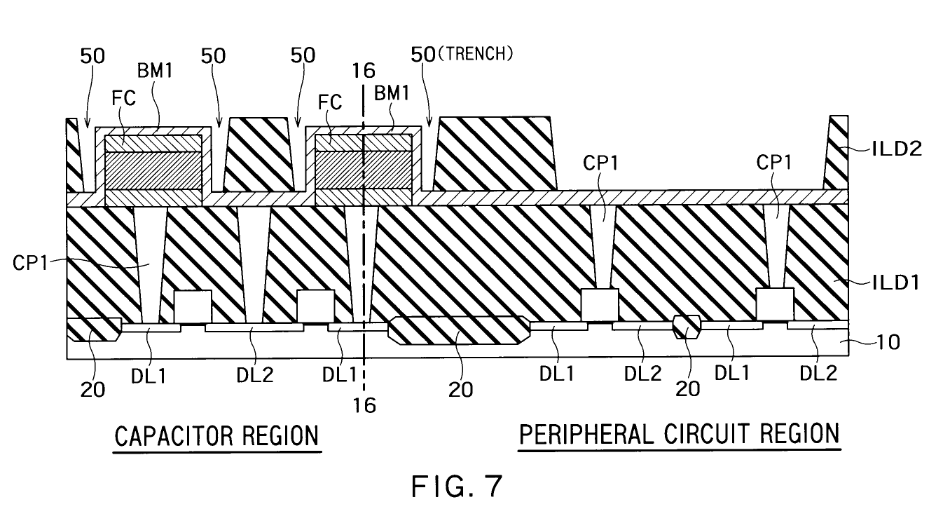

Next, as shown in FIG. 7, the interlayer dielectric film ILD2 around the ferroelectric capacitor FC and the interlayer dielectric film ILD2 in the peripheral circuit regions are etched by using lithography and RIE. In this case, the barrier film BM1 is used as an etching stopper. Accordingly, a trench 50 is formed around the ferroelectric capacitor FC, while leaving the barrier film BM1 as it is. The trench 50 is formed to surround the ferroelectric capacitor FC on the plane surface as observed from above the front surface of the silicon substrate 10. The trench 50 is provided to form a space between the ferroelectric capacitor FC and the interlayer dielectric film ILD2.

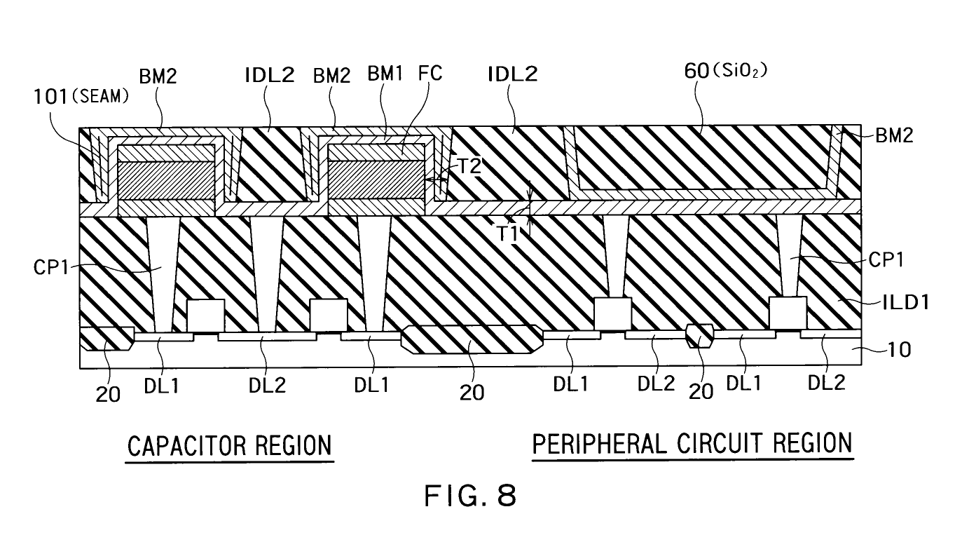

Next, as shown in FIG. 8, the barrier film BM2 is filled into the trench 50. In this case, the barrier film BM2 is also deposited on the barrier film BM1 of the peripheral circuit region. The barrier film BM2 includes Al₂O₃, SiN, and TiO₂, for example. While the barrier film BM2 is sufficiently filled into the trench 50, the film thickness of the barrier film BM2 deposited into the peripheral circuit region is preferably sufficiently small. This is because when the barrier film BM2 is thin in the peripheral circuit region, the contact (the contact plug CP2) connected to the contact plug CP1 can be formed easily. Further, in this step, the barrier film BM2 is simultaneously deposited on the side surface of the barrier film BM1 and on the side surface of the interlayer dielectric film ILD2. Accordingly, the barrier film BM2 which is a single continuous layer is deposited in the trench 50 so as to be folded down between a side surface of the barrier film BM1 and a side surface of the interlayer dielectric film ILD2. As a result, a seam 101 is formed in the barrier film BM2.

An embedded insulation film 60 is deposited onto the barrier film BM2 and the interlayer dielectric film ILD2. The embedded insulation film 60 includes a P-TEOS film, an O₃-TEOS film, an SOG, or a Low-k film (SiOF, SiOC), for example. The embedded insulation film 60 is flattened using CMP. At the same time, the barrier film BM2 is also flattened. As a result, a structure as shown in FIG. 8 is obtained. The barrier films BM1, BM2 formed on the side surface of the ferroelectric capacitor FC have the thickness T2, and this T2 is larger than the thickness T1.

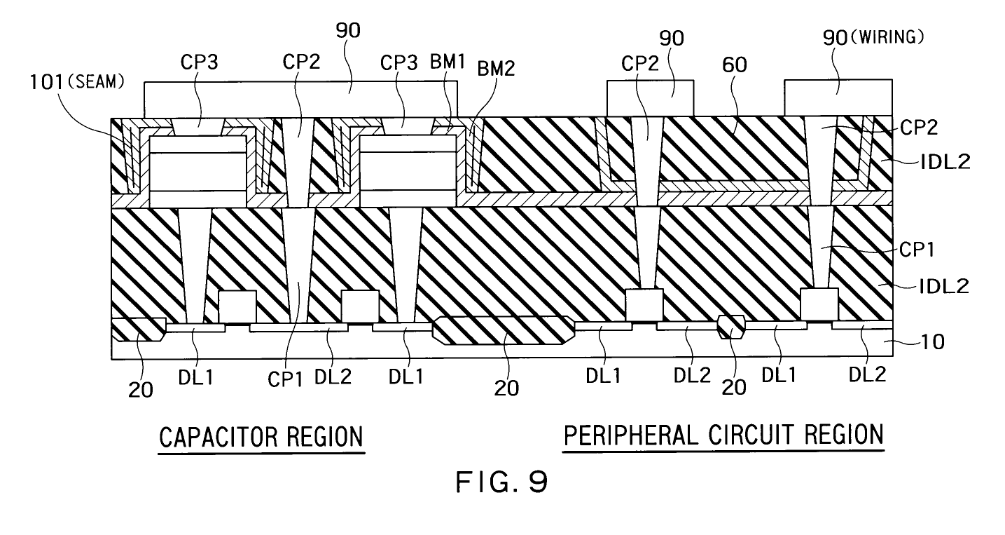

Next, a contact hole is formed on the upper electrode TE of the ferroelectric capacitor FC and on a part of the contact plug CP1 by using lithography and RIE. A metal material is embedded into a contact hole, and this metal material is flattened using CMP. In this CMP process, the metal material is ground until when the upper surface of the interlayer dielectric film ILD2 and the embedded material 60 is exposed. As a result, as shown in FIG. 9, the contact plugs CP2 and CP3 are formed. A metal material of the contact plugs CP2 and CP3 includes any one of W, Al, TiN, Cu, Ti, Ta, and TaN, for example. The metal material can be deposited by MOCVD, sputtering, plating, or sputter-reflow.

Next, a wiring material is deposited onto the contact plugs CP2 and CP3, the interlayer dielectric film ILD2, and the embedded insulation film 60, and this wiring material is processed in a desired wiring pattern. Accordingly, as shown in FIG. 9, the wiring 90 is formed. The wiring material is a metal material including any one of W, Al, TiN, Cu, Ti, Ta, and TaN, for example.

According to the present embodiment, not only the barrier film BM1 but also the barrier film BM2 is also provided on the side surface of the ferroelectric capacitor FC. Therefore, the film thickness T2 of the barrier films BM1 and BM2 on the side surface of the ferroelectric capacitor FC is larger than the film thickness T1 of the barrier film BM1 on the upper surface of the interlayer dielectric film ILD1. Accordingly, in the tungsten deposition process of forming the contact plugs CP1, CP2, and CP3, the barrier films BM1 and BM2 on the side surface of the ferroelectric capacitor FC can sufficiently suppress the hydrogen from entering the side surface of the ferroelectric capacitor FC.

In the present embodiment, the thickness T1 of the barrier film BM1 on the upper surface of the interlayer dielectric film ILD1 is smaller than the thickness T2. Accordingly, in the process of forming the contact hole, the etching amount of the barrier film BM1 can be small. Because the etching of the barrier film takes a long time, a small etching amount of the barrier film can shorten the etching process.

Conventionally, the barrier film BM1 has a large thickness to form the barrier film in a large thickness on the side surface of the ferroelectric capacitor. In this case, to deposit the barrier film of the desired thickness T2 on the side surface of the ferroelectric capacitor, it has been necessary to deposit a barrier film having a larger thickness than T2 on the upper surface of the interlayer dielectric film ILD1. This not only consumes a large amount of the barrier film material but also requires a long time in the etching process to form the contact hole.

In the present embodiment, the barrier film BM1 is deposited on the side surface of the ferroelectric capacitor FC, and further, the barrier film BM2 is filled into the trench 50 formed around the ferroelectric capacitor FC. Accordingly, the barrier films BM1 and BM2 having a sufficient thickness can be formed on the side surface of the ferroelectric capacitor FC to suppress the entering of hydrogen, while depositing the barrier film BM1 in a sufficiently small thickness on the interlayer dielectric film ILD1. The ferroelectric memory and the manufacturing method thereof according to the present embodiment do not have the above conventional inconveniences.

According to the present embodiment, the barrier film BM2 is formed to fill in the trench 50 formed around the ferroelectric capacitor FC. In this case, the barrier film BM2 is deposited on both the side surface of the trench 50 (the side surface of the interlayer dielectric film ILD2) and the side surface of the ferroelectric capacitor FC. Therefore, the trench 50 is filled in fast with the barrier film BM2. When a barrier film is deposited on the side surface of the ferroelectric capacitor FC in a state that the trench 50 and the interlayer dielectric film ILD2 are not provided, for example, the barrier film BM2 is deposited on only the side surface of the ferroelectric capacitor FC. On the other hand, in the present embodiment, the barrier film BM2 is deposited on both the side surface of the trench 50 (the side surface of the interlayer dielectric film ILD2) and the side surface of the ferroelectric capacitor FC. Therefore, in the present embodiment, the barrier film BM2 can be formed fast (or in a large thickness) on the side surface of the ferroelectric capacitor FC. For example, in a case that the barrier film BM2 consisting of an ALD-Al₂O₃ layer having 60 nm thickness is deposited only on a side surface of the ferroelectric capacitor FC, it takes 30 minutes. In contrast, in the present embodiment, it is sufficient that the ALD-Al₂O₃ layer is deposited 30 nm thickness to obtain the ALD-Al₂O₃ layer having 60 nm thickness. Therefore, it takes approximately 15 minutes.

Thus, because the barrier film BM2 is simultaneously deposited on the side surface of the barrier film BM1 and the side surface of the interlayer dielectric film ILD2, the thickness of the barrier film BM2 in the present invention can be around half of that of the conventional technique.

In the present embodiment, a single layer of the barrier film BM2 is formed so as to be folded down into a trench 50, and the seam 101 is formed inside of the barrier film BM2. Therefore, it is possible to reduce a probability that a defect in the barrier film BM2 extends and reaches to the ferroelectric capacitor FC. For example, even if a pin-hole is generated at an interface between the barrier film BM2 and the interlayer dielectric film ILD2, the pin-hole can be stopped at the seam 101.

### Second Embodiment

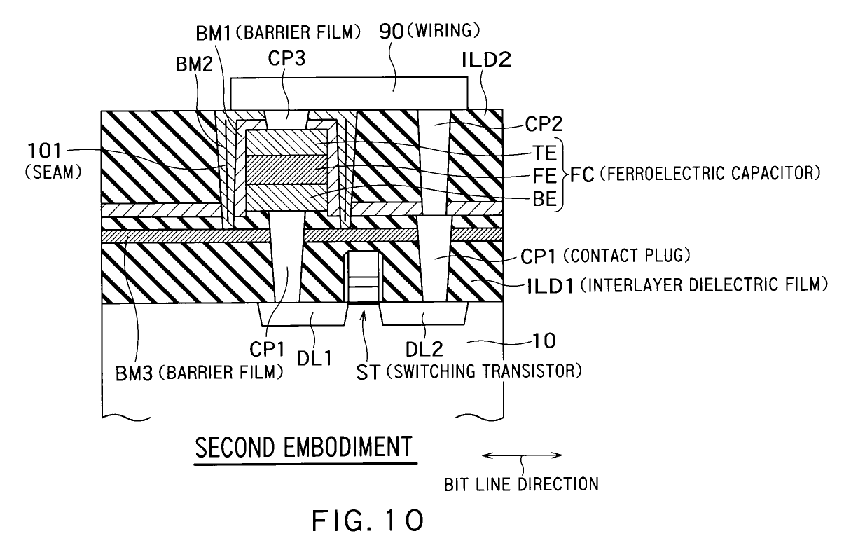

FIG. 10 is a cross-sectional view of a ferroelectric memory according to a second embodiment of the present invention. In the second embodiment, the ferroelectric memory further includes a bottom barrier film BM3 within the interlayer dielectric film ILD1 beneath the ferroelectric capacitor FC. Further, in the second embodiment, the barrier film BM2 extends to below the ferroelectric capacitor FC along the side surface of the ferroelectric capacitor FC, and reaches the barrier film BM3 piercing through a part of the barrier film BM1 and the interlayer dielectric film ILD1. Other configurations according to the second embodiment can be similar to those according to the first embodiment.

The barrier film BM3 includes a single-layer film of Al₂O₃, SiN, and TiO₂, or a lamination film of two or more layers of these films. The barrier film BM3 also has a characteristic of suppressing percolation of hydrogen, and interrupting hydrogen. When the barrier film BM3 is provided beneath the ferroelectric capacitor FC, hydrogen is suppressed from entering the lower part of the ferroelectric capacitor FC. The barrier film BM2 is connected to the barrier film BM around the ferroelectric capacitor FC. Accordingly, the ferroelectric capacitor FC is completely covered by the barrier films BM1 to BM3, except the contact portion between the contact plugs CP1 and CP3. Therefore, in the second embodiment, hydrogen can be more sufficiently suppressed from entering the ferroelectric capacitor FC.

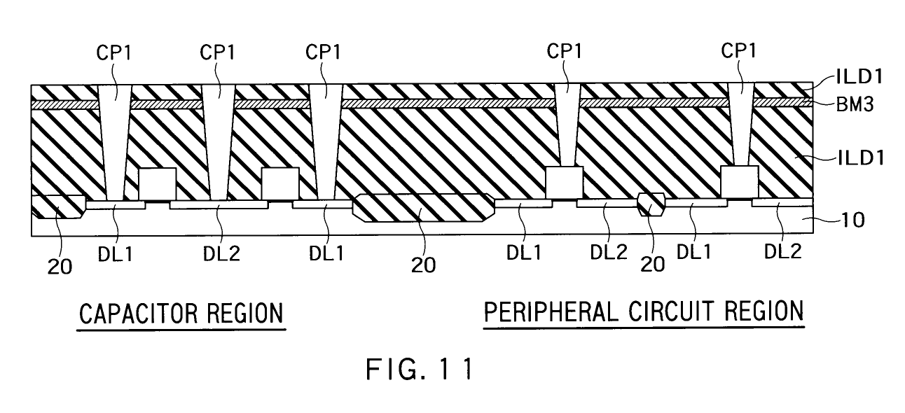

A method of manufacturing the ferroelectric memory according to the second embodiment is explained with reference to FIG. 11 to FIG. 15. First, the structure as shown in FIG. 3 is formed, like in the first embodiment. Next, the barrier film BM3 is deposited, and the interlayer dielectric film ILD1 is deposited on the barrier film BM3, as shown in FIG. 11. A contact hole communicating to the diffusion layers DL1 and DL2 is formed within the interlayer dielectric film ILD1 and the barrier film BM3 by using lithography and RIE. Further, metal or doped polysilicon is embedded into the contact hole, and the metal or the doped polysilicon is flattened using CMP. As a result, the contact plug CP1 is formed as shown in FIG. 11. The contact plug CP1 in the capacitor region and the contact plug CP1 in the peripheral circuit region can be formed simultaneously, or can be formed in separate processes.

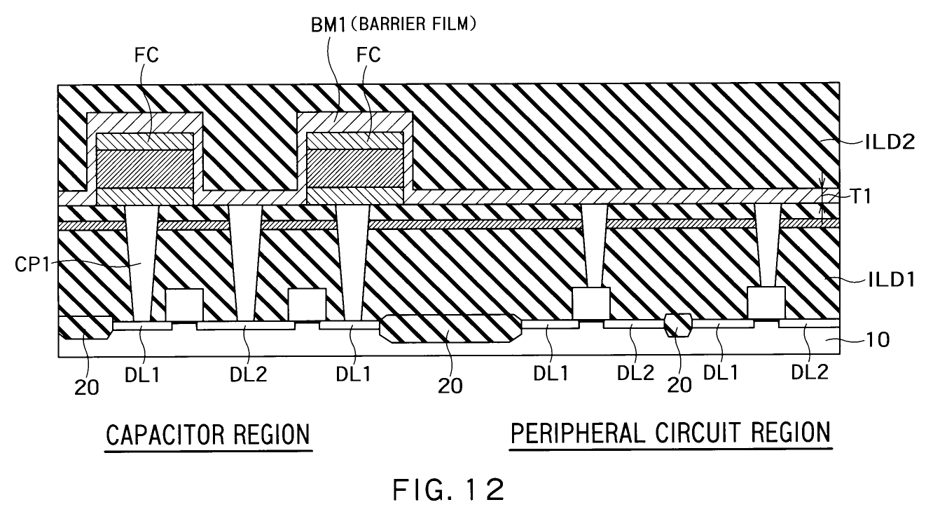

Next, the ferroelectric capacitor FC is formed on the contact plug CP1, like in the first embodiment. The barrier film BM1 is deposited on the side surface and the upper surface of the ferroelectric capacitor FC, and on the interlayer dielectric film ILD1. The interlayer dielectric film ILD2 is deposited on the barrier film BM1, and the interlayer dielectric film ILD2 is flattened using CMP. As a result, a structure as shown in FIG. 12 is obtained.

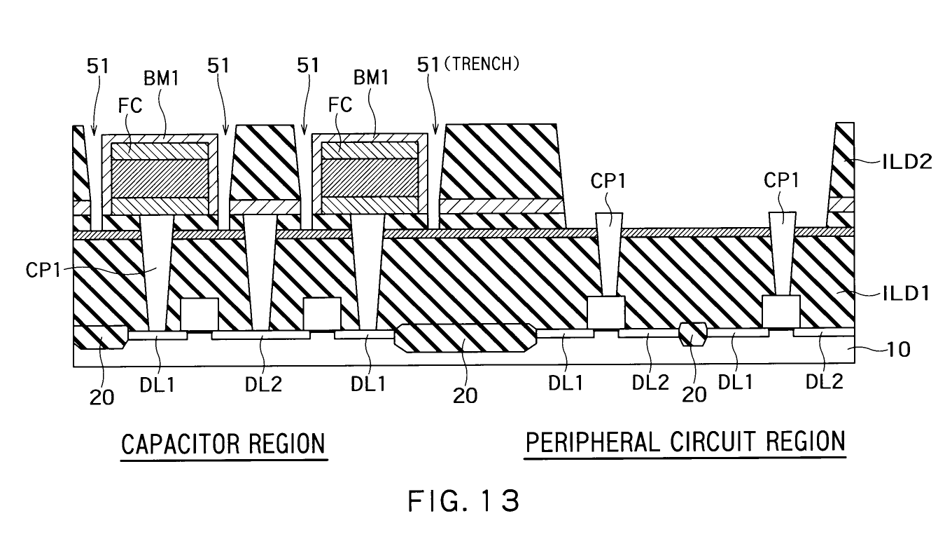

The interlayer dielectric film ILD2 around the ferroelectric capacitor FC and the interlayer dielectric film ILD2 in the peripheral circuit region are etched by using lithography and RIE, as shown in FIG. 7. The barrier film BM1 exposed to the bottom of the trench is etched. The interlayer dielectric film ILD1 exposed by etching the barrier film BM1 is also etched. As a result, a trench 51 reaching the barrier film BM3 is formed around the ferroelectric capacitor FC, as shown in FIG. 13. In this case, the upper parts of the barrier film BM1 and the upper parts of the interlayer dielectric film ILD1 in the peripheral circuit region are also removed in self-alignment.

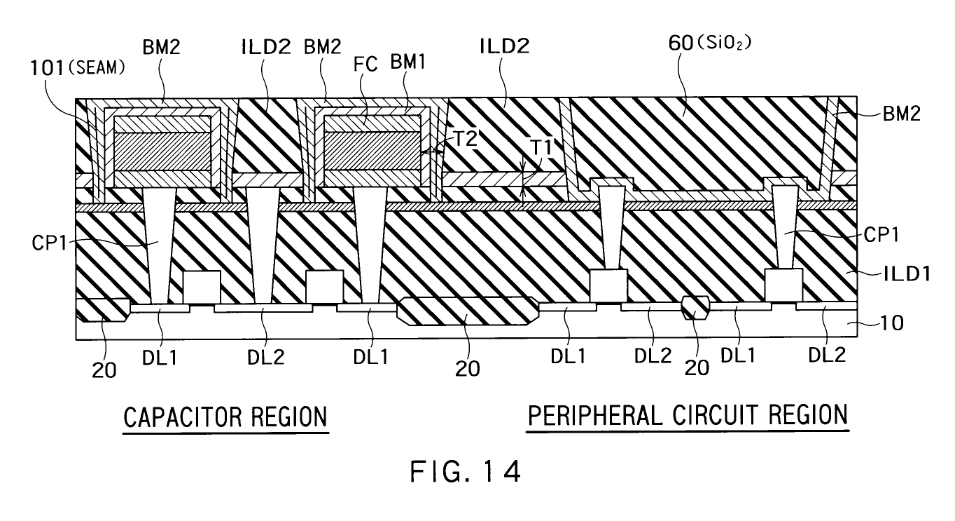

Next, the barrier film BM2 is filled into the trench 51, as shown in FIG. 14. In this case, the barrier film BM2 is also deposited on the barrier film BM1 in the peripheral circuit region. While sufficiently filling the barrier film BM2 into the trench 51, it is preferable that the barrier film BM2 deposited in the peripheral circuit region is as thin as possible. This is because the contact (the contact plug CP2) connected to the contact plug CP1 is formed easily in the peripheral circuit region. Further, in this step, the barrier film BM2 is simultaneously deposited on the side surface of the barrier film BM1 and on the side surface of the interlayer dielectric film ILD2. Accordingly, the barrier film BM2 which is a single continuous layer is deposited in the trench 50 so as to be folded down between a side surface of the barrier film BM1 and a side surface of the interlayer dielectric film ILD2. As a result, a seam 101 is formed in the barrier film BM2.

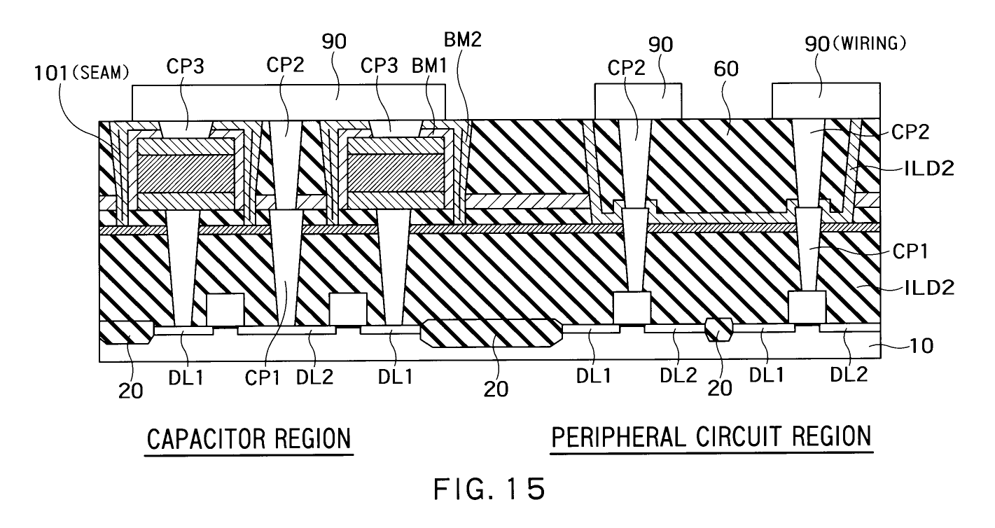

Thereafter, the embedded insulation film 60 is deposited onto the barrier film BM2 and the interlayer dielectric film ILD2, like in the first embodiment. The embedded insulation film 60 is flattened using CMP. At the same time, the barrier film BM2 is also flattened. The contact plugs CP2 and CP3, and the wiring 90 are formed. As a result, a structure as shown in FIG. 15 is obtained.

The ferroelectric capacitor FC is completely covered by the barrier films BM1 to BM3, except the contact portion between the contact plugs CP1 and CP3. Therefore, in the second embodiment, hydrogen can be more sufficiently suppressed from entering the ferroelectric capacitor FC. In the second embodiment, effects similar to those in the first embodiment can be obtained.

### Third Embodiment

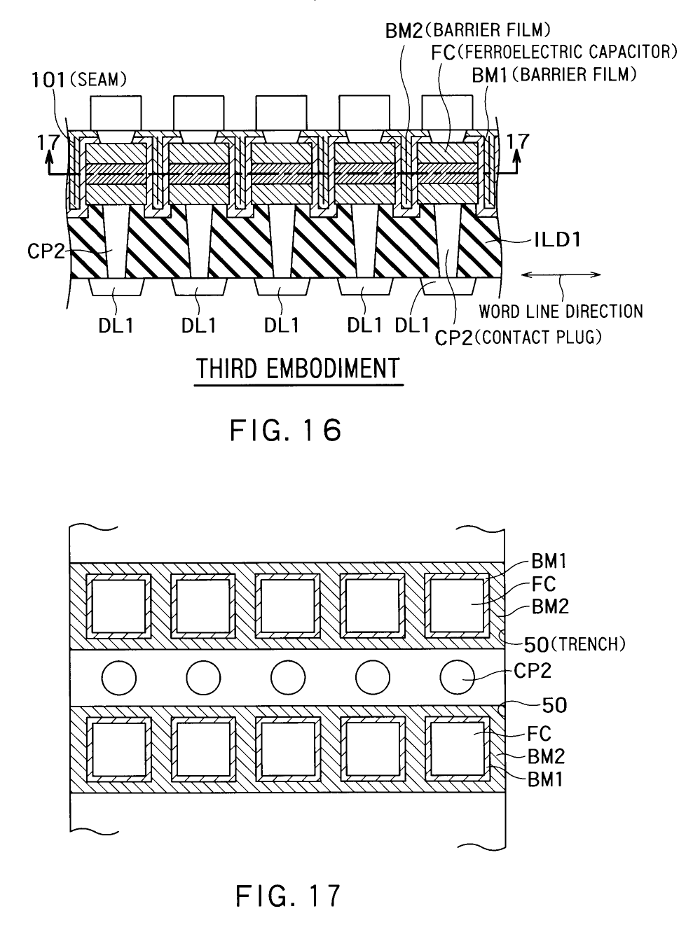

FIG. 16 is a cross-sectional view of a ferroelectric memory according to a third embodiment of the present invention. FIG. 16 corresponds to a cross section along a line 16-16 in FIG. 1. That is, FIG. 16 shows a cross section in a second direction (a word line direction) perpendicular to a bit line direction. FIG. 17 is a top plan view of a layer along a line 17-17 in FIG. 16. FIG. 17 is simplified to make clear a layout relationship among the trench 50, the ferroelectric capacitor FC, and the contact plug CP2.

In the third embodiment, the barrier film BM2 is filled into between the side surfaces of plural adjacent ferroelectric capacitors FC arranged in the word line direction.

The barrier film BM2 is a single continuous layer folded down into a trench 50 between two ferroelectric capacitors FC adjacent to each other. The barrier film BM2 is provided on side surfaces of the two ferroelectric capacitors FC via the barrier film BM1. The barrier film BM2 includes a seam 101 extending along with a side surface of the ferroelectric capacitors FC and a side surface of the barrier film BM1. The seam 101 is provided at an intermediate portion between the two ferroelectric capacitors FC.

The barrier film BM2 extends to the word line direction corresponding to each row of the plural ferroelectric capacitors FC arranged in the word line direction, and is isolated between the ferroelectric capacitors FC adjacent in the bit line direction. While the contact plug CP2 is present between the ferroelectric capacitors FC adjacent in the bit line direction, the barrier film BM2 is not provided around the contact plug CP2. Other configurations of the third embodiment can be similar to those of the first embodiment.

In a method of manufacturing a ferroelectric memory according to the third embodiment, in the forming process of trench 50, the trench 50 extending to the word line direction is formed to correspond to each row of plural ferroelectric capacitors FC arranged in the word line direction. More specifically, in the cross section along the line 16-16 in FIG. 7, the trench 50 is formed in a line shape to include the whole rows of ferroelectric capacitors on the plane surface as shown in FIG. 17. Other processes of the manufacturing method in the third embodiment can be similar to the processes of the manufacturing method in the first embodiment. As a result, the ferroelectric memory according to the third embodiment is completed.

The barrier film BM2 is simultaneously deposited on the barrier film BM1 between the two ferroelectric capacitors FC adjacent to each other. Accordingly, the barrier film BM2 which is a single continuous layer is deposited in the trench 50 so as to be folded down between the side surfaces of the two ferroelectric capacitors FC. As a result, a seam 101 is formed in the barrier film BM2.

In the third embodiment, the trench 50 is not provided for each ferroelectric capacitor FC, but is provided in a line shape to include a whole row of ferroelectric capacitors including plural ferroelectric capacitors. Therefore, the trench 50 can be formed relatively easily. Further, effects similar to those in the first embodiment can be obtained in the third embodiment.

### Fourth Embodiment

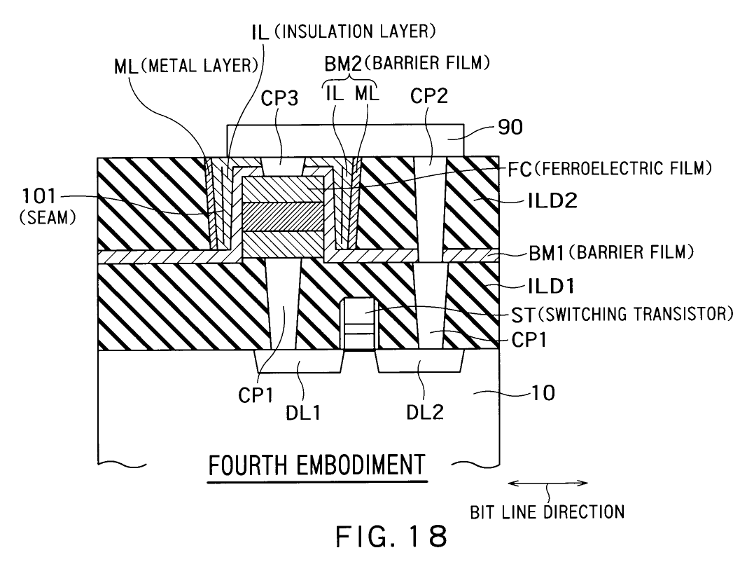

FIG. 18 is a cross-sectional view of a ferroelectric memory according to a fourth embodiment of the present invention. The fourth embodiment is different from the first embodiment in that the barrier film BM2 has a lamination structure of an insulation layer IL and the metal layer ML. Other configurations of the fourth embodiment can be similar to those of the first embodiment.

In the fourth embodiment, the insulation layer IL is provided on the side surface of the ferroelectric capacitor FC via the barrier film BM1, and the metal layer ML is provided at the outside of the insulation layer IL. The insulation layer IL includes Al₂O₃, SiN, or TiO₂, for example. The metal layer ML includes any one of Al, Ti, TiN, and TiAlN. Because the metal layer ML is provided on the side surface of the insulation layer IL, diffusion of hydrogen to the ferroelectric capacitor FC can be further suppressed.

### Fifth Embodiment

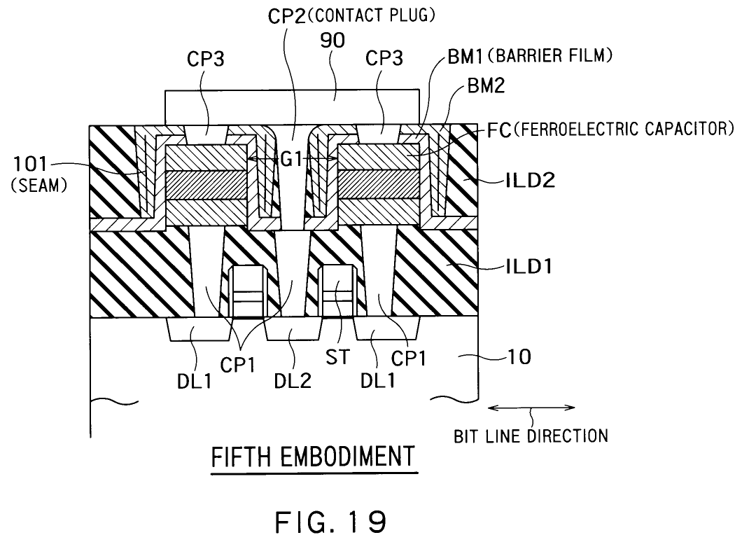

FIG. 19 is a cross-sectional view of a ferroelectric memory according to a fifth embodiment of the present invention. In the fifth embodiment, the contact plug CP2 provided between the side surfaces of the ferroelectric capacitors FC adjacent in the bit line direction is formed in self-alignment contact using the barrier film BM2 as a mask. Therefore, the barrier film BM2 is filled in around the second contact plug between the side surfaces of the ferroelectric capacitors FC adjacent in the bit line direction. Other configurations according to the fifth embodiment can be similar to those according to the first embodiment.

When the contact plug CP2 is formed in self-alignment contact, an interval G1 between the ferroelectric capacitors FC adjacent in the bit line direction can be decreased. Accordingly, the size of the memory cell can be more decreased.

As shown in FIG. 7, at the time of forming the trench 50, the interlayer dielectric film ILD2 can be formed in a forward tapered shape. Accordingly, when the barrier film BM2 is embedded into the trench 50, the barrier film BM2 can be formed in an inverse tapered shape. That the barrier film BM2 is in the inverse tapered shape is preferable as the mask of the contact plug CP2. If the mask is in the forward tapered shape, the thickness of the mask at the upper part of the ferroelectric capacitor is smaller than the thickness at the lower part of the ferroelectric capacitor. Therefore, when the contact hole is formed in self-alignment, the upper part of the mask is etched more than the lower part of the mask. As a result, there is a risk that the contact plug CP2 is short-circuited with the ferroelectric capacitor FC. In the fifth embodiment, the barrier film BM2 is in the inversely tapered shape. That is, the thickness of the mask at the upper part of the side surface of the ferroelectric capacitor is larger than the thickness of the mask at the lower part of the side surface of the ferroelectric capacitor. As a result, in the fifth embodiment, even when the contact plug CP2 is formed in self-alignment contact, there is small risk that the contact plug CP2 is short-circuited with the ferroelectric capacitor FC.

### Sixth Embodiment

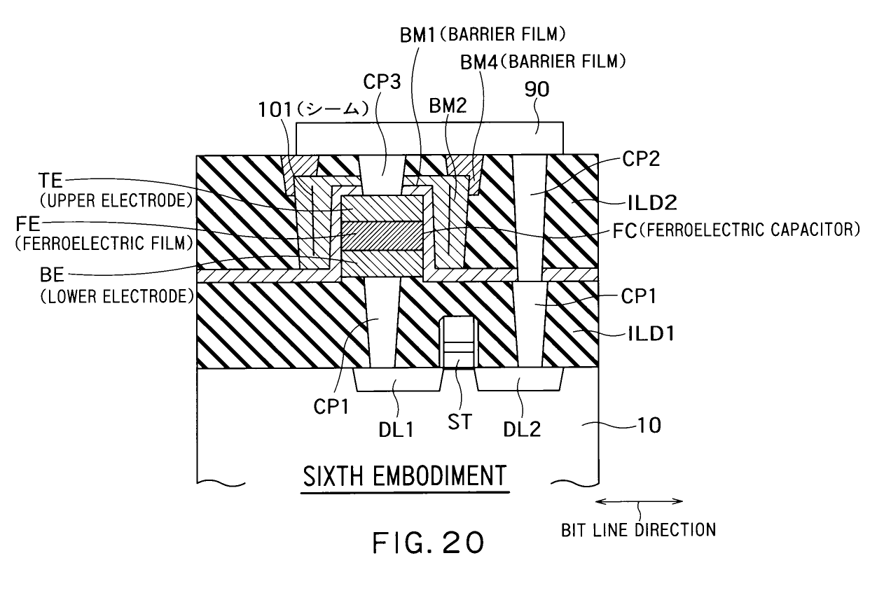

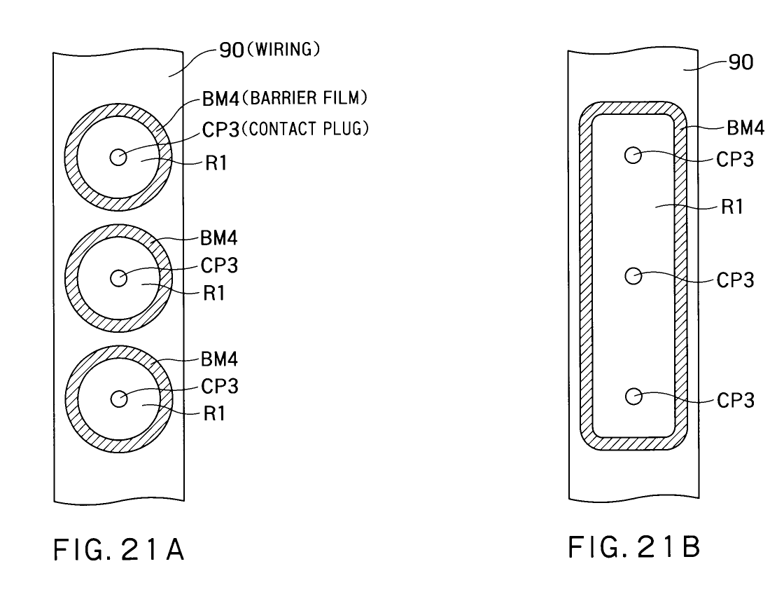

FIG. 20 is a cross-sectional view of a ferroelectric memory according to a sixth embodiment of the present invention. In the sixth embodiment, on the plane surface as observed from above the front surface of the silicon substrate 10, an upper barrier film BM4 surrounds the contact plug CP3 connected to the upper electrode TE, within the interlayer dielectric film ILD2 between the wiring 90 and the upper electrode TE, as shown in FIG. 21A or FIG. 21B. A number of the contact plug CP3 that the upper barrier film BM4 surrounds can be one as shown in FIG. 21A, or can be plural as shown in FIG. 21B. Other configurations of the sixth embodiment can be similar to the configurations of the first embodiment. The barrier film BM4 includes a single-layer film of Al₂O₃, SiN, and TiO₂, or a lamination film of two or more layers of these materials.

When the upper barrier film BM4 is not present, hydrogen entering the region not provided with the wiring 90 is diffused to the ferroelectric capacitor FC via a boundary between the contact plug CP3 and the barrier film BM1. However, according to the sixth embodiment, because the upper barrier film BM4 encircles the contact plug CP3, the hydrogen entering the region not provided with the wiring 90 is not diffused to the ferroelectric capacitor FC via the boundary between the contact plug CP3 and the barrier film BM1. To sufficiently exhibit this effect, as shown in FIG. 21A and FIG. 21B, on the plane surface as observed from above the front surface of the silicon substrate 10, the region R1 surrounded by the upper barrier film BM4 is covered with the wiring 90. It is preferable that the upper surface of the interlayer dielectric film ILD2 is not exposed within this region R1. The upper barrier film BM4 can be formed before or after the process of forming the contact plug CP3.

### Seventh Embodiment

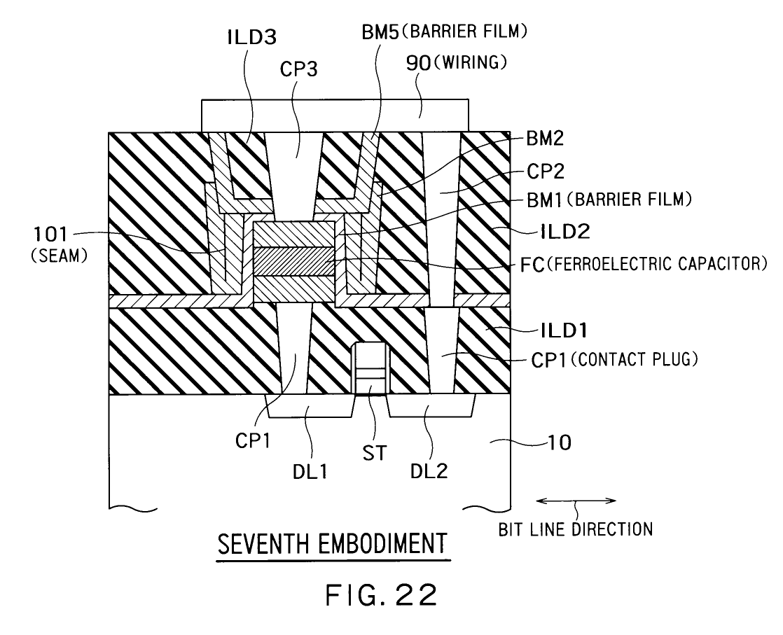

FIG. 22 is a cross-sectional view of a ferroelectric memory according to a seventh embodiment of the present invention. In the seventh embodiment, on the plane surface as observed from above the front surface of the silicon substrate 10, an upper barrier film BM5 surrounds the contact plug CP3 connected to the upper electrode TE, within the interlayer dielectric film ILD2, like the upper barrier film BM4 in the sixth embodiment. A number of the contact plug CP3 that the upper barrier film BM5 surrounds can be one as shown in FIG. 21A, or can be plural as shown in FIG. 21B. Other configurations of the seventh embodiment can be similar to those of the first embodiment. The upper barrier film BM5 includes a single-layer film of Al₂O₃, SiN, and TiO₂, or a lamination film of two or more layers of these materials.

According to the seventh embodiment, because the upper barrier film BM5 surrounds the contact plug CP3, effects similar to those of the sixth embodiment can be obtained. To sufficiently exhibit these effects, on the plane surface as observed from above the front surface of the silicon substrate 10, the region surrounded by the barrier film BM5 is covered by the wiring 90. In this region, the upper surface of the interlayer dielectric film ILD2 is preferably not exposed.

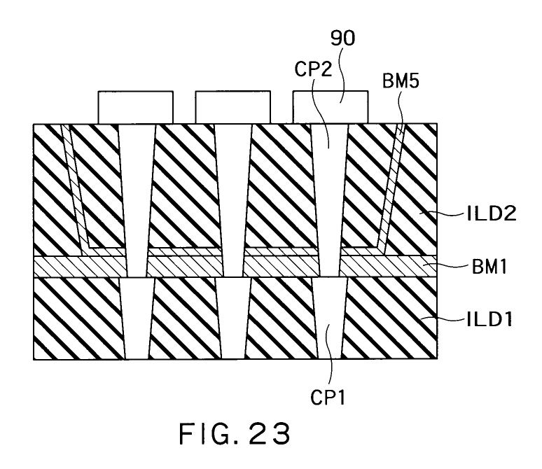

FIG. 23 is a cross-sectional view showing a contact portion of the peripheral circuit region of the ferroelectric memory according to the seventh embodiment. In the seventh embodiment, the upper barrier film BM5 also surrounds the periphery of the contact portion of the peripheral circuit region. Accordingly, hydrogen can be suppressed from entering the contact region of the peripheral circuit.

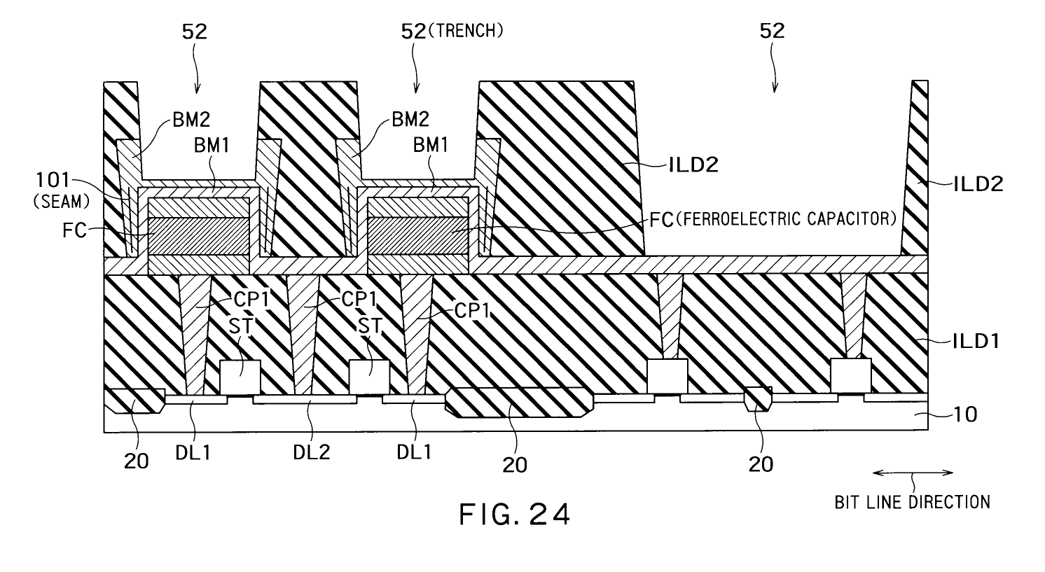

A manufacturing method according to the seventh embodiment is explained. The structure shown in FIG. 8 in the first embodiment is obtained. Thereafter, the interlayer dielectric film is deposited on the barrier film BM2 and the interlayer dielectric film ILD2. Accordingly, the interlayer dielectric film ILD2 is made thicker. Next, the interlayer dielectric film ILD2 in the formation region of the upper barrier film BM5, and the barrier film BM2 are removed, thereby forming a trench 52. As a result, a structure as shown in FIG. 24 is obtained.

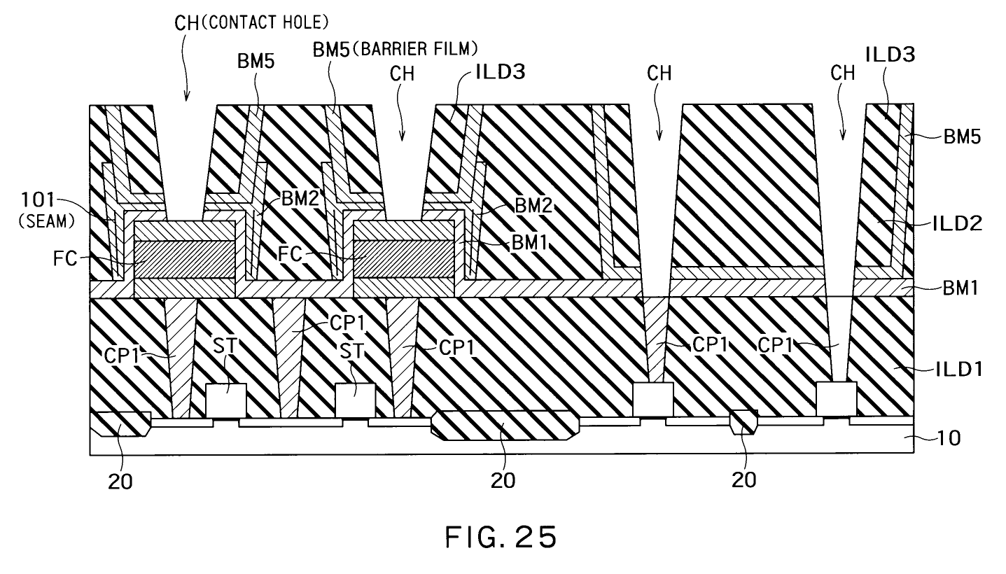

Next, as shown in FIG. 25, the upper barrier film BM5 is deposited thinly, and thereafter, the interlayer dielectric film ILD3 is deposited. The interlayer dielectric film ILD3 is flattened using CMP. Next, a contact hole CH is formed by etching the barrier film BM5 and the barrier film BM1. As a result, a structure as shown in FIG. 25 is obtained. A metal material is filled into the control hole to form the contact plug CP3. Thereafter, the ferroelectric memory as shown in FIG. 22 and FIG. 23 is completed, through a process similar to that of the first embodiment.

According to the seventh embodiment, the contact hole can be formed easily by forming the barrier film BM1 and the upper barrier film BM5 thin. Further, effects similar to those in the first embodiment can be obtained in the seventh embodiment.

The second embodiment can be combined with any one of the third to the seventh embodiment. In this case, the third to the seventh embodiments can also obtain the effects of the second embodiment. The barrier film BM2 in the fourth to the seventh embodiments can be filled into between the ferroelectric capacitors FC adjacent in the word line direction, like the barrier film BM2 in the third embodiment. Accordingly, the fourth to seventh embodiments can also obtain the effects of the third embodiment.

1. A semiconductor device comprising:
a switching transistor provided on a semiconductor substrate;
an interlayer dielectric film formed on the switching transistor;
a ferroelectric capacitor including an upper electrode, a ferroelectric film, and a lower electrode formed on the interlayer dielectric film;
a contact plug provided in the interlayer dielectric film and electrically connected to the lower electrode;
a diffusion layer connecting between the contact plug and the switching transistor;
a trench formed around the ferroelectric capacitor; and
a barrier film filling in the trench and provided on a side surface of the ferroelectric capacitor and on an upper surface of the interlayer dielectric film, the barrier film suppressing percolation of hydrogen, wherein
a thickness of the barrier film on the side surface of the ferroelectric capacitor is larger than a thickness of the barrier film on the upper surface of the interlayer dielectric film.

2. The semiconductor device according to claim 1, wherein the barrier film includes a first barrier film deposited on the side surface of the ferroelectric capacitor and on the upper surface of the interlayer dielectric film and includes a second barrier film filling in the trench.

3. The semiconductor device according to claim 2, wherein
the second barrier film is a single continuous layer folded down into the trench along with a side surface of the first barrier film and with a side surface of the interlayer dielectric film.

4. The semiconductor device according to claim 1, further comprising:
a bottom barrier film provided in the interlayer dielectric film below the ferroelectric capacitor and suppressing percolation of hydrogen, wherein
the barrier film extends to below the ferroelectric capacitor along the side surface of the ferroelectric capacitor and is connected to the bottom barrier film.

5. The semiconductor device according to claim 1, wherein
a plurality of the ferroelectric capacitors are arranged in a first direction, and
the barrier film is filled between the plurality of adjacent ferroelectric capacitors.

6. The semiconductor device according to claim 5, wherein
the barrier film includes:
a first barrier film provided on side surfaces of a plurality of ferroelectric capacitors adjacent to each other;
a second barrier film which is a single continuous layer folded down into a trench between the ferroelectric capacitors adjacent to each other.

7. The semiconductor device according to claim 5, wherein
a plurality of the ferroelectric capacitors arranged in the first direction form a ferroelectric capacitor row,
a plurality of the ferroelectric capacitor rows are arranged in a second direction crossing the first direction in a stripe shape, and
the barrier film is not filled into between a plurality of adjacent ferroelectric capacitor rows.

8. The semiconductor device according to claim 1, wherein
the barrier film includes a first barrier film deposited on the side surface of the ferroelectric capacitor and on the upper surface of the interlayer dielectric film, an insulation film provided on the side surface of the ferroelectric capacitor via the first barrier film, and a metal film provided on the side surface of the ferroelectric capacitor via the first barrier film and the insulation film.

9. The semiconductor device according to claim 1, wherein
a plurality of the ferroelectric capacitors are arranged, and
a contact plug formed in self-alignment by using the barrier film is formed between the side surfaces of the plurality of the ferroelectric capacitors.

10. The semiconductor device according to claim 9, wherein
the side surface of the barrier film is formed in an inverse tapered shape.

11. The semiconductor device according to claim 1, further comprising:
an upper contact plug provided on the upper electrode;
an upper barrier film formed on the barrier film to surround the periphery of the upper contact plug; and
a wiring formed on the upper contact plug and on the upper barrier film.

12. The semiconductor device according to claim 11, wherein the upper barrier film is formed to surround the periphery of the plurality of upper contact plugs.

13. The semiconductor device according to claim 11, wherein
the upper barrier film is formed to surround the periphery of a contact plug of a peripheral circuit region formed around a memory region in which the ferroelectric capacitor is formed.

14. A method of manufacturing a semiconductor device comprising a ferroelectric capacitor including an upper electrode, a ferroelectric film, and a lower electrode, the manufacturing method comprising:
forming a switching transistor on a semiconductor substrate and forming a diffusion layer connected to the switching transistor;
forming a first interlayer dielectric film on the switching transistor;
forming a contact plug connected to the diffusion layer in the first interlayer dielectric film;
forming the ferroelectric capacitor on the contact plug;
depositing a first barrier film suppressing percolation of hydrogen on the ferroelectric capacitor and on the first interlayer dielectric film;
depositing a second interlayer dielectric film on the first barrier film;
forming a trench between the side surface of the ferroelectric capacitor and the second interlayer dielectric film by etching the second interlayer dielectric film around the ferroelectric capacitor; and
filling a second barrier film into the trench.

15. The method of manufacturing a semiconductor device according to claim 14, wherein
the second barrier film is simultaneously deposited on the first barrier film between the two ferroelectric capacitors adjacent to each other, so that the second barrier film is folded down between the side surfaces of the two ferroelectric capacitors.

16. The method of manufacturing a semiconductor device according to claim 14, further comprising:
forming a contact plug in self-alignment by using the second barrier film as a mask between a plurality of the adjacent ferroelectric capacitors.

17. The method of manufacturing a semiconductor device according to claim 14, wherein
at the time of forming the first interlayer dielectric film, a third barrier layer embedded in the first interlayer dielectric film is formed,
the contact plug is formed to reach the diffusion layer piercing through the third barrier layer, and
the trench is formed to reach the third barrier film.

18. The method of manufacturing a semiconductor device according to claim 14, wherein
at the time of forming the trench,
a plurality of the ferroelectric capacitors are arranged in a first direction, and the trench is formed in self-alignment by using the first barrier film as a mask between the side surfaces of a plurality of the adjacent ferroelectric capacitors,
a plurality of the ferroelectric capacitors arranged in a first direction form a ferroelectric capacitor row,
a plurality of the ferroelectric capacitor rows are arranged in a second direction crossing the first direction in a stripe shape, and
the trench is formed between the side surface of the ferroelectric capacitor and the second interlayer dielectric film and between a plurality of the adjacent ferroelectric capacitor rows.

19. The method of manufacturing a semiconductor device according to claim 14, further comprising:
depositing a third interlayer dielectric film on the second barrier film;
forming a second trench reaching the upper part of the second barrier layer piercing through the third interlayer dielectric film by etching the third interlayer dielectric film and the second barrier layer on the upper electrode;
depositing a fourth barrier film on the inside surface of the second trench;
depositing a fourth interlayer dielectric film in the second trench; and
forming a contact plug reaching the upper electrode piercing through the fourth interlayer dielectric film, the fourth barrier film, the second barrier film, and the first barrier film on the upper electrode.
